(19) United States
(12) Patent Application Publication
(10) Pub. No.: US 2013/0334640 A1
(43) Pub. Date: Dec. 19, 2013

(54) IMAGE SENSOR, IMAGE PROCESSING DEVICE INCLUDING THE SAME, AND METHOD OF FABRICATING THE SAME

(71) Applicant: SAMSUNG ELECTRONICS CO., LTD., Suwon-si (KR)

(72) Inventor: Hyun Seok LEE, Hwaseong-si (KR)

(73) Assignee: SAMSUNG ELECTRONICS CO., LTD., Suwon-si (KR)

(21) Appl. No.: 13/833,832

(22) Filed: Mar. 15, 2013

(30) Foreign Application Priority Data
Jun. 18, 2012 (KR) 10-2012-0065196

(51) Int. Cl. H01L 31/0232

(52) U.S. Cl. CPC H01L 31/02325
USPC 257/432; 438/72

(57) ABSTRACT

An image sensor includes a dielectric layer including a reflector, a photo-electric conversion region on the dielectric layer, and a resonance layer on the photo-electric conversion region, the resonance layer including ribbed materials arranged in a concentric pattern.

### CROSS-REFERENCE TO RELATED APPLICATION

The present application claims priority under 35 U.S.C. §119 to Korean Patent Application No. 10-2012-0065196, filed on Jun. 18, 2012, in the Korean Intellectual Property Office, and entitled: “Image Sensor, Image Processing Device Including The Same And Method Of Fabricating The Same,” which is incorporated by reference herein in its entirety

### BACKGROUND

1. Field

Embodiments of the inventive concept relate to an image sensor, and more particularly, to an image sensor using surface plasmon resonance, photonic crystal grating scattering, or optical reflection, an image processing device including the same, and a method of fabricating the image sensor.

2. Description of the Related Art

Image sensors are devices that convert an optical image into an electrical signal. Recently, with the development of computer and communications industry, demand for image sensors with improved performance is increasing in various fields, such as digital cameras, camcorder, personal communication systems (PCSs), game machines, security cameras, medical micro-cameras, and robots. To acquire a three-dimensional (3D) image using image sensors, information about color and information about the depth or distance between a target object and an image sensor are required.

Methods of acquiring information about the distance between the target object and the image sensor may be largely divided into passive methods, e.g., used in stereo cameras, and active methods. For example, in the passive methods, the distance is calculated using only image information of the target object without radiating light at the target object. In another example, in the active methods, triangulation and time-of-flight (TOF) may be used. The triangulation is the process of emitting light using a light source, e.g., a laser, separated from the image sensor by a predetermined distance, sensing light reflected from the target object, and calculating the distance between the target object and the image sensor using the sensing result. The TOF is the process of calculating the distance between the target object and the image sensor using a time taken for light emitted to the target object to come back after being reflected from the target object.

Image sensors include complementary metal-oxide semiconductor (CMOS) image sensors and charge-coupled device (CCD) image sensors. CMOS image sensors have less power consumption, lower manufacturing cost, and smaller size than CCD image sensors and have thus been used widely in mobile devices, e.g., smart phones and digital cameras.

### SUMMARY

According to some embodiments of the inventive concept, there is provided an image sensor including a dielectric layer including a reflector, a photo-electric conversion region on the dielectric layer, and a resonance layer on the photo-electric conversion region, the resonance layer including ribbed materials arranged in a concentric pattern.

The photo-electric conversion region may include a light-absorbing layer below the resonance layer, and a photogate disposed between the light-absorbing layer and the dielectric layer.

The image sensor may further include a dielectric film between the light-absorbing layer and the resonance layer.

The light-absorbing layer may have a thickness of about 0.01 μm to about 20.

The photo-electric conversion region may include an electron donating material and an electron accepting material.

The resonance layer may be configured to support surface plasmon resonance at a wavelength of light to be sensed.

The ribbed materials may have a negative real value of permittivity at a wavelength of light to be sensed.

The ribbed materials may be patterns spaced apart from each other, the patterns having a permittivity relatively greater than a permittivity of a material in a space between adjacent patterns.

A distance between the photo-electric conversion region and the reflector may be about 700 nm or less.

The dielectric layer may include at least one of SiO₂, SiON, HfO₂, and Si₃N₄.

An image processing device may include the image sensor, and s processor configured to control an operation of the image sensor.

According to some embodiments of the inventive concept, there is also provided a method of fabricating an image sensor including forming a first semiconductor substrate, forming a photo-electric conversion region on the first semiconductor substrate, forming a dielectric layer on a first surface of the photo-electric conversion region, the dielectric layer including a reflector, bonding a second semiconductor substrate to the dielectric layer and removing the first semiconductor substrate, and forming a resonance layer on a second surface of the photo-electric conversion region, the resonance layer including ribbed materials arranged in a concentric pattern.

Forming the photo-electric conversion region may include forming a light-absorbing layer on the first semiconductor substrate, and forming a photogate on a part of the first surface.

Forming the photo-electric conversion region may include forming a first region of an electron donating material and a second region of an electron accepting material on the first semiconductor substrate.

Forming the resonance layer may include forming a dielectric film on the second surface, and forming the resonance layer on the dielectric film.

According to some embodiments of the inventive concept, there is also provided an image sensor including a dielectric layer including a reflector, a photo-electric conversion region on the dielectric layer, and a resonance layer on the photo-electric conversion region, the resonance layer including ribbed materials arranged in a concentric pattern on the photo-electric conversion region, and the photo-electric conversion region being between the resonance layer and the dielectric layer.

The ribbed material of the resonance layer may include a plurality of closed-shaped patterns spaced apart from each other.

A distance between adjacent patterns in the resonance layer may be based on a wavelength of light to be sensed and on a distance between a bottom of the resonance layer and a bottom of the photo-electric conversion region.

The photo-electric conversion region may be between the resonance layer and the reflector of the dielectric layer.

The image sensor may further include a microlens on the photo-electric conversion region, the resonance layer being between the microlens and the photo-electric conversion region.

### BRIEF DESCRIPTION OF THE DRAWINGS

FIG. 1 illustrates a cross-sectional view of a pixel according to some embodiments of the inventive concept;

FIG. 2 illustrates a cross-sectional view of a pixel according to other embodiments of the inventive concept;

FIG. 3 illustrates a cross-sectional view of a pixel according to further embodiments of the inventive concept;

FIG. 4 illustrates a cross-sectional view of a pixel according to other embodiments of the inventive concept;

FIG. 5 illustrates a cross-sectional view of a pixel according to yet other embodiments of the inventive concept;

FIG. 6 illustrates a cross-sectional view of a pixel according to still other embodiments of the inventive concept;

FIG. 7 illustrates a plan view of examples of a resonance layer illustrated in FIG. 1, 3, 4, or 6;

FIG. 8 illustrates a plan view of examples of a resonance layer illustrated in FIG. 2 or 5;

FIG. 9 illustrates a flowchart of a method of fabricating an image sensor according to some embodiments of the inventive concept;

FIGS. 10A through 10E illustrate sectional views of stages in a method of fabricating an image sensor according to some embodiments of the inventive concept;

FIG. 11 illustrates a flowchart of a method of fabricating an image sensor according to other embodiments of the inventive concept;

FIGS. 12A through 12D illustrate sectional views of stages in a method of fabricating an image sensor according to other embodiments of the inventive concept;

FIG. 13 illustrates a schematic block diagram of an image sensor including a pixel illustrated in any one of FIGS. 1 through 6;

FIG. 14 illustrates a schematic block diagram of an image processing device including an image sensor illustrated in FIG. 13; and

FIG. 15 illustrates a schematic block diagram of an interface and an electronic system including an image sensor with the pixel in any one of FIGS. 1 through 6.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

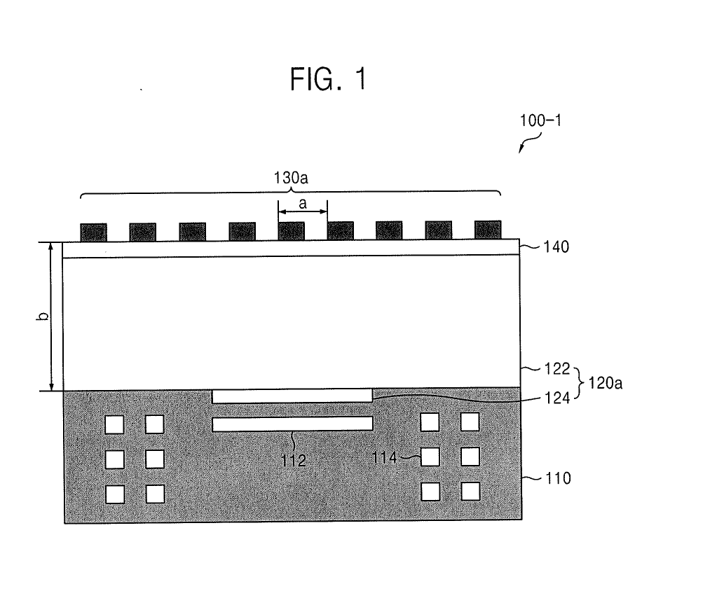

FIG. 1 illustrates a cross-sectional view of a pixel 100-1 according to some embodiments of the inventive concept. The pixel 100-1 may include a dielectric layer 110, a photo-electric conversion region 120a, and a resonance layer 130a.

The dielectric layer 110 may be implemented by a dielectric substance, e.g., silicon dioxide (SiO₂), silicon oxynitride (SiON), hafnium dioxide (HfO₂), and/or silicon nitride (Si₃N₄), but the inventive concept is not restricted thereto. A reflector 112 and a plurality of electrodes 114 may be arranged, e.g., embedded, in the dielectric layer 110.

The reflector 112 may be spread wide in the dielectric layer 110 so as to reflect light incident on the pixel 100-1, e.g., the reflector 112 may be in a center of the dielectric layer 110 to extend in parallel to a bottom of the dielectric layer 110. The reflector 112 may have a thickness of about 200 nm, but the thickness of the reflector 112 is not restricted thereto. The reflector 112 may be formed of a metal having a negative real value of the permittivity at the wavelength(s) of light to be sensed. For instance, the reflector 112 may be formed of aluminum (Al), gold (Au), silver (Ag), copper (Cu) or an alloy thereof, but the inventive concept is not restricted thereto.

Each of the electrodes 114 may be arranged in the dielectric layer 110 to receive a corresponding control signal for controlling the pixel 100-1 or to output an electrical signal from the pixel 100-1. For example, the electrodes 114 may be in a peripheral region of the dielectric layer 110.

The photo-electric conversion region 120a converts incident light into an electrical signal. The photo-electric conversion region 120a may include a light-absorbing layer 122 and a photogate 124.

The light-absorbing layer 122 absorbs incident light and generates electrons and/or holes in accordance with the incident light. The light-absorbing layer 122 may be formed on the dielectric layer 110 of intrinsic silicon or extrinsic silicon, but the inventive concept is not restricted thereto. For instance, the light-absorbing layer 122 may be formed of one of silicon (Si) materials, germanium (Ge) materials, and Si—Ge materials or of an organic or inorganic semiconductor material having a photo-electric conversion characteristic. The thickness of the light-absorbing layer 122 may be about 0.01 μm to about 20 μm but is not restricted thereto. For example, the light-absorbing layer 122 may be flat with a substantially uniform thickness, e.g., measured along a normal to the dielectric layer 110.

The photogate 124 absorbs the electrons and/or holes generated by the light-absorbing layer 122 and generates an electrical signal based on the absorbed electrons and/or holes. The photogate 124 may be formed of, e.g., amorphous silicon, polysilicon, or extrinsic silicon, but the inventive concept is not restricted thereto.

The photogate 124 may be electrically connected with one of the electrodes 114 and may output the electrical signal corresponding to the intensity of incident light in response to a signal output from the electrode 114. Although the photogate 124 is exemplified in the current embodiments, it may be replaced with a different photo-electric conversion device, e.g., a photodiode or a photo transistor. The distance between the reflector 112 and the photo-electric conversion region 120a, i.e., a distance between the reflector 112 and the photogate 124, may be about 700 nm or less.

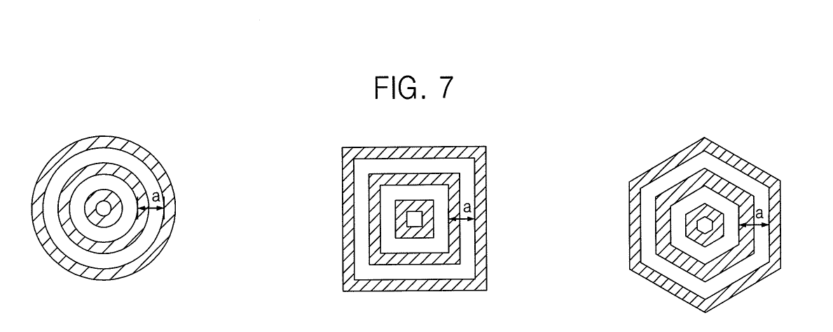

The resonance layer 130a may include ribbed materials, e.g., an uneven structure or a non-flat structure, arranged on the photo-electric conversion region 120a in a concentric pattern. For example, the resonance layer 130a may include a plurality of closed-shaped patterns, e.g., ribs, spaced apart from each other and arranged in a concentric configuration, as illustrated and will be described in more detail below with reference to FIG. 7.

The photo-electric conversion region 120a may be between the resonance layer 130a and the dielectric layer 110, so the resonance layer 130a allows surface plasmon resonance to occur at the wavelength of the light to be sensed. That is, the resonance layer 130a may collect incident light and reflect or collect light reflected from the reflector 112 in the dielectric layer 110 using the surface plasmon resonance, thereby increasing the light absorption factor of the pixel 100-1.

For example, the ribbed material, i.e., the ribs, in the resonance layer 130a may be formed of a metal having a negative real value of the permittivity at the wavelength(s) of light to be sensed. For instance, the metal may be Al, Au, Ag, Cu, or an alloy thereof, but the inventive concept is not restricted thereto. In another example, the ribbed material may be formed of a material with a permittivity (or a refractive index) relatively higher than a permittivity (or a refractive index) of a material in a space between adjacent ribs. For instance, when there is air in the space between adjacent ribs, the ribs may be formed of silicon having a permittivity of about 11.7 since air has a permittivity of about 1.

For example, the permittivity (or a refractive index) of the ribs may have a value close to that of the light-absorbing layer 122. When the permittivity (or a refractive index) of the material of the ribs is the same as that of the material of the light-absorbing layer 122, a distance “a” between adjacent ribs may be defined by Equation 1 below.

$$a = \frac{2 π}{\sqrt{\frac{2 π n}{λ} - {( \frac{m π}{b} )}^{2}}} \qquad Equation 1$$

In Equation 1, “n” is the refractive index of the material of the ribs and the light-absorbing layer 122, “λ” is the wavelength of the light to be sensed, “m” is an integer, and “b” is a distance between a lowest most surface of the resonance layer 130a and a lowest most surface of the light-absorbing layer 122 (FIG. 1). At this time, the resonance layer 130a may reflect light reflected from the reflector 112, thereby increasing the light absorption factor of the pixel 100-1.

The pixel 100-1 may also include a dielectric film 140 between the resonance layer 130a and the photo-electric conversion region 120a. For example, the dielectric film 140 may be between the light-absorbing layer 122 and the resonance layer 130a.

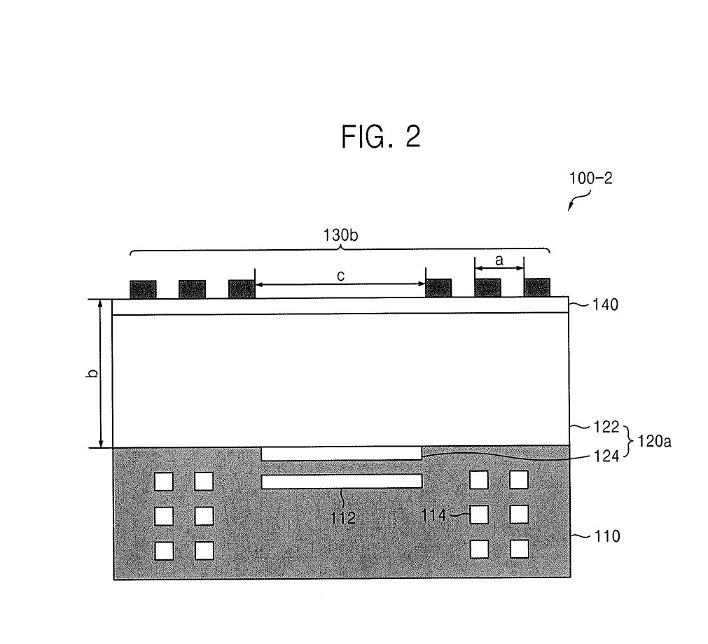

FIG. 2 illustrates a cross-sectional view of a pixel 100-2 according to other embodiments of the inventive concept. Referring to FIG. 2, the pixel 100-2 may include the dielectric layer 110, the photo-electric conversion region 120a, a resonance layer 130b, and the dielectric film 140. The structures and the functions of the dielectric layer 110, the photo-electric conversion region 120a, and the dielectric film 140 illustrated in FIG. 2 are substantially the same as those of the dielectric layer 110, the photo-electric conversion region 120a, and the dielectric film 140 illustrated in FIG. 1. Thus, detailed descriptions thereof will be omitted.

The resonance layer 130b may include ribbed materials (or uneven structure or not flat structure) arranged on the photo-electric conversion region 120a in a concentric pattern having a hole with a diameter of “c” at its center. The diameter “c” may be defined in Equation 2 below.

$$c = k \frac{2 π}{{λ}^{′}} \qquad Equation 2$$

In Equation 2, “k” is a positive integer and “λ′” is a plasmon resonance wavelength for the light to be sensed. The resonance layer 130b may collect incident light using surface plasmon resonance, transmit the collected light to the photo-electric conversion region 120a through the hole with the diameter “c”, and collect light reflected from the reflector 112, thereby enhancing the effect of light collection of the light-absorbing layer 122 and eventually increasing the light absorption factor of the pixel 100-2.

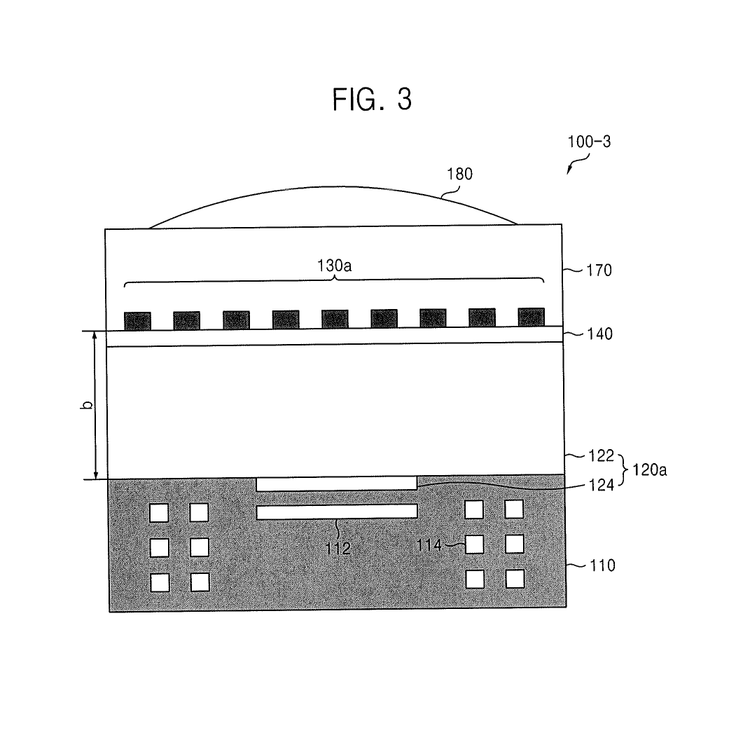

FIG. 3 illustrates a cross-sectional view of a pixel 100-3 according to further embodiments of the inventive concept. Referring to FIG. 3, the pixel 100-3 may include the dielectric layer 110, the photo-electric conversion region 120a, the resonance layer 130a, the dielectric film 140, an overcoat layer 170, and a microlens 180.

The structures and the functions of the dielectric layer 110, the photo-electric conversion region 120a, the resonance layer 130a, and the dielectric film 140 illustrated in FIG. 3 are substantially the same as those of the dielectric layer 110, the photo-electric conversion region 120a, the resonance layer 130a, and the dielectric film 140 illustrated in FIG. 1. Thus, detailed descriptions thereof will be omitted.

The overcoat layer 170 may be formed on the resonance layer 130a and protect the resonance layer 130a. The permittivity of the overcoat layer 170 may be less than that of the material of the resonance layer 130a and the light-absorbing layer 122.

The microlens 180 may be formed on the overcoat layer 170 and may focus incident light on the photo-electric conversion region 120a. Since the incident light is focused on the photo-electric conversion region 120a by the microlens 180, the light absorption factor of the pixel 100-3 can be increased.

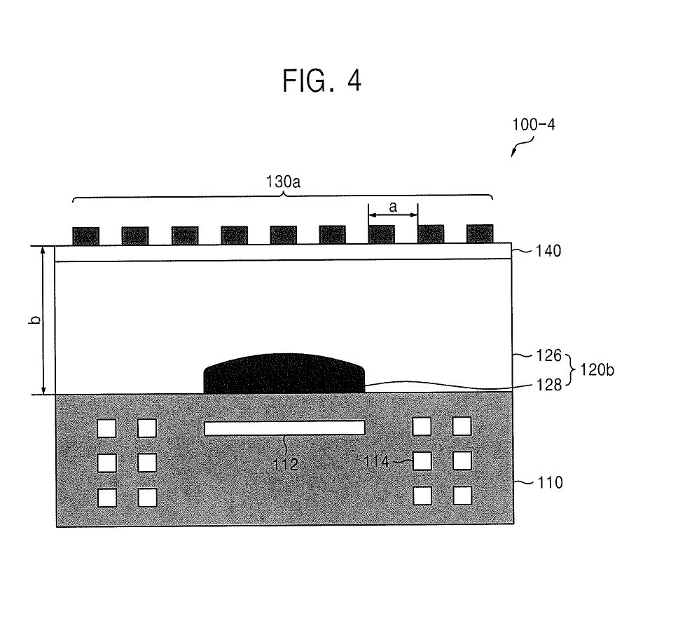

FIG. 4 illustrates a cross-sectional view of a pixel 100-4 according to other embodiments of the inventive concept. Referring to FIG. 4, the pixel 100-4 may include the dielectric layer 110, a photo-electric conversion region 120b, the resonance layer 130a, and the dielectric film 140.

The structures and the functions of the dielectric layer 110, the resonance layer 130a, and the dielectric film 140 illustrated in FIG. 4 are substantially the same as those of the dielectric layer 110, the resonance layer 130a, and the dielectric film 140 illustrated in FIG. 1. Thus, detailed descriptions thereof will be omitted.

The photo-electric conversion region 120b may include a first region 126 and a second region 128. The first region 126 may be formed of one of an electron donating material and an electron accepting material. The second region 128 may be formed of the other one of the electron donating material and the electron accepting material. For example, when the first region 126 is formed of an electron donating material, the second region 128 may be formed of an electron accepting material. In another example, when the first region 126 is formed of an electron accepting material, the second region 128 may be formed of an electron donating material. In other words, when the first region 126 is an N-doped semiconductor, the second region 128 is a P-doped semiconductor. Similarly, when the first region 126 is a P-doped semiconductor, the second region 128 is an N-doped semiconductor.

The second region 128 may be electrically connected with at least two of the electrodes 114 included in the dielectric layer 110 and may output an electrical signal corresponding to the intensity of light incident on one of the at least two electrodes 114 in response to a signal output from another one of the at least two electrodes 114.

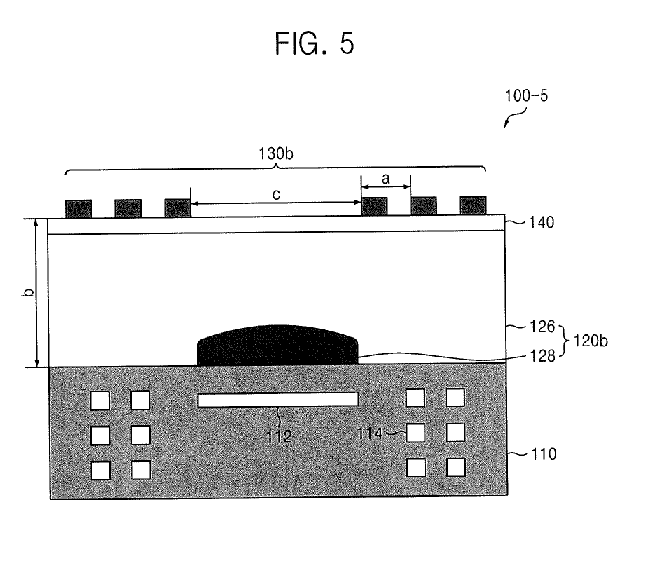

FIG. 5 illustrates a cross-sectional view of a pixel 100-5 according to yet other embodiments of the inventive concept. Referring to FIG. 5, the pixel 100-5 may include the dielectric layer 110, the photo-electric conversion region 120b, the resonance layer 130b, and the dielectric film 140. The structures and the functions of the dielectric layer 110, the photo-electric conversion region 120b, and the dielectric film 140 illustrated in FIG. 5 are substantially the same as those of the dielectric layer 110, the photo-electric conversion region 120b, and the dielectric film 140 illustrated in FIG. 4. Thus, detailed descriptions thereof will be omitted. The structure and the function of the resonance layer 130b illustrated in FIG. 5 is substantially the same as those of the resonance layer 130b illustrated in FIG. 2. Thus, detailed descriptions thereof will be omitted.

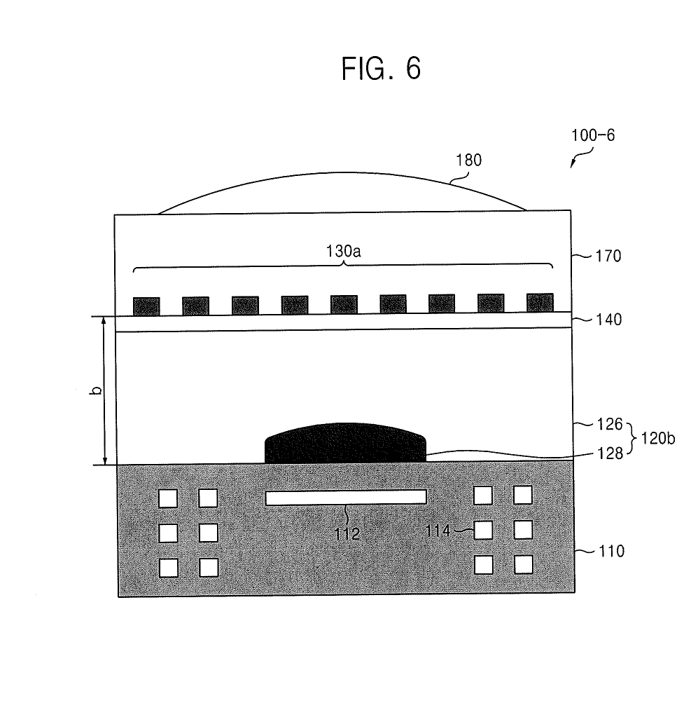

FIG. 6 illustrates a cross-sectional view of a pixel 100-6 according to still other embodiments of the inventive concept. Referring to FIG. 6, the pixel 100-6 may include the dielectric layer 110, the photo-electric conversion region 120b, the resonance layer 130a, the dielectric film 140, the overcoat layer 170, and the microlens 180.

The structures and the functions of the dielectric layer 110, the resonance layer 130a, the dielectric film 140, the overcoat layer 170, and the microlens 180 illustrated in FIG. 6 are substantially the same as those of the dielectric layer 110, the resonance layer 130a, the dielectric film 140, the overcoat layer 170, and the microlens 180 illustrated in FIG. 3. Thus, detailed descriptions thereof will be omitted. In addition, the structure and the function of the photo-electric conversion region 120b illustrated in FIG. 6 is substantially the same as those of the photo-electric conversion region 120b illustrated in FIG. 4. Thus, detailed descriptions thereof will be omitted.

FIG. 7 illustrates a plan view of examples of the resonance layer 130a illustrated in FIG. 1, 3, 4, or 6. Referring to FIGS. 1, 3, 4, 6, and 7, the resonance layer 130a may include ribbed materials in a concentric pattern. For example, the resonance layer 130a may include a plurality of closed-shaped ribs with increasing diameters and arranged around a same center.

The distance “a” between the ribs may be designed to allow surface plasmon resonance or photonic crystal grating scattering to occur. The distance “a” may be determined by the wavelength of light to be sensed and/or the distance “b” between the bottom of the resonance layer 130a and the bottom of the light-absorbing layer 122 (in FIG. 1). The resonance layer 130a may function as a color filter according to the distance “a” between the materials. As illustrated in FIG. 7, the concentric pattern may be concentric circles or concentric polygons.

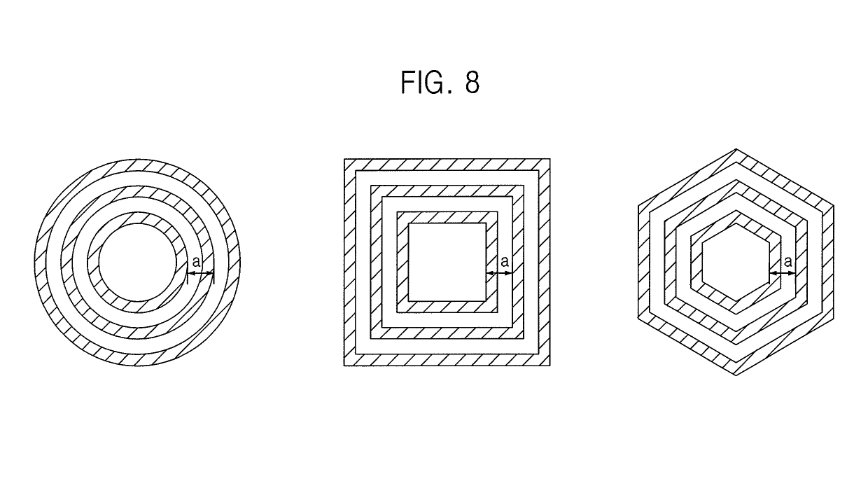

FIG. 8 illustrates a plan view of examples of the resonance layer 130b illustrated in FIG. 2 or 5. Referring to FIGS. 2, 5, and 8, the resonance layer 130b may include ribbed materials (or uneven structure or not flat structure) in a concentric pattern having a hole with the diameter “c” at its center. The diameter “c” may be determined by the wavelength of the light to be sensed. The resonance layer 130b may collect incident light using surface plasmon resonance and may transmit the collected light to the photo-electric conversion region 120a through the hole with the diameter “c”.

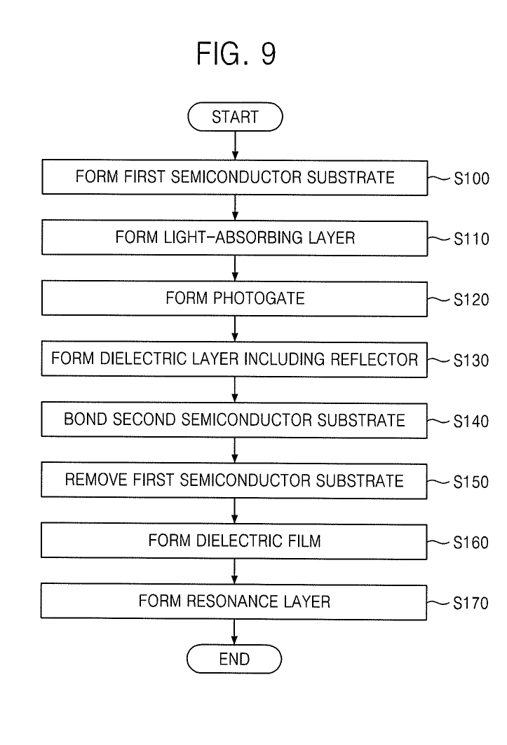

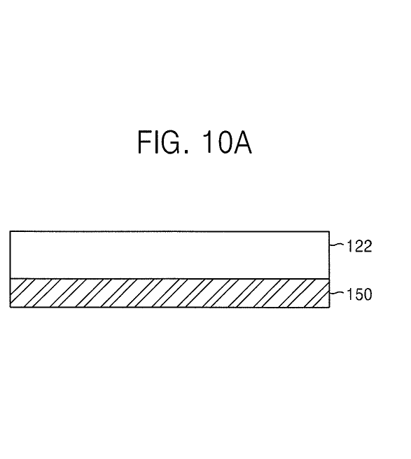

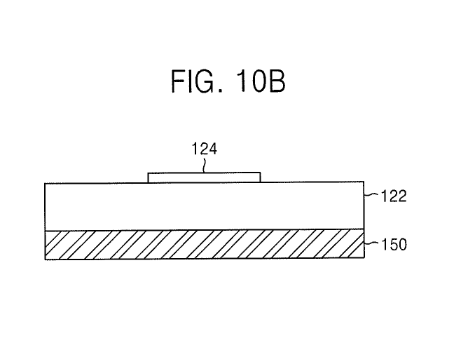

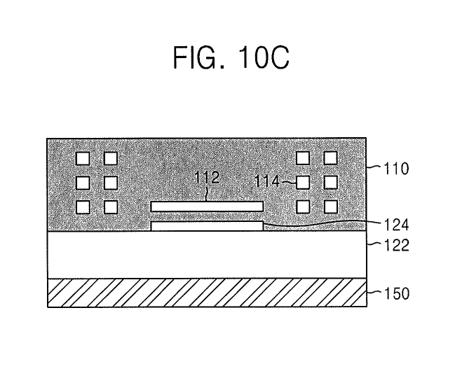

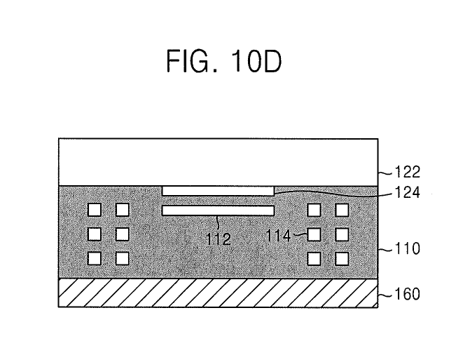

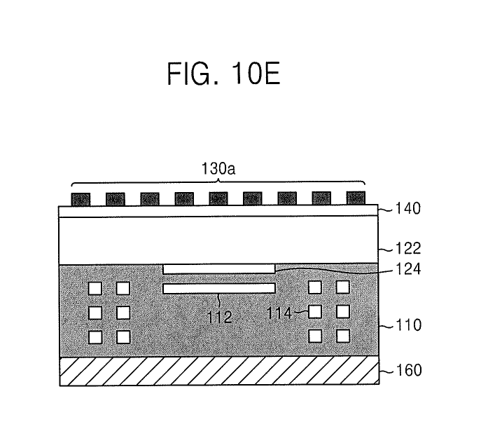

FIG. 9 illustrates a flowchart of a method of fabricating an image sensor according to some embodiments of the inventive concept. FIGS. 10A through 10E are sectional views of stages in the method illustrated in FIG. 9.

Referring to FIG. 9 and FIGS. 10A through 10E, a first semiconductor substrate 150 is formed in operation S100. The photo-electric conversion region 120a is formed on the first semiconductor substrate 150. In detail, as shown in FIG. 10A, the light-absorbing layer 122 is formed on the first semiconductor substrate 150 in operation S110.

As shown in FIG. 10B, the photogate 124 is formed on a part of the light-absorbing layer 122 in operation S120. As shown in FIG. 10C, the dielectric layer 110 including the reflector 112 is formed on a first surface of the photo-electric conversion region 120a, e.g., a side opposite the first semiconductor substrate 150, in operation S130. At this time, the reflector 112 may be formed after a part of the dielectric layer 110 is formed. Thereafter, the rest of the dielectric layer 110 may be formed.

After the dielectric layer 110 is formed, as shown in FIG. 10D, a second semiconductor substrate 160 is bonded to the dielectric layer 110 in operation S140. The first semiconductor substrate 150 is removed in operation S150.

After the first semiconductor substrate 150 is removed, as shown in FIG. 10E, the resonance layer 130a or 130b (generically denoted by 130) is formed on a second surface of the photo-electric conversion region 120a from which the first semiconductor substrate 150 is removed, e.g., a side opposite the first surface. The dielectric film 140 may be formed on the light-absorbing layer 122 in operation S160, and the resonance layer 130 may be formed on the dielectric film 140 in operation S170.

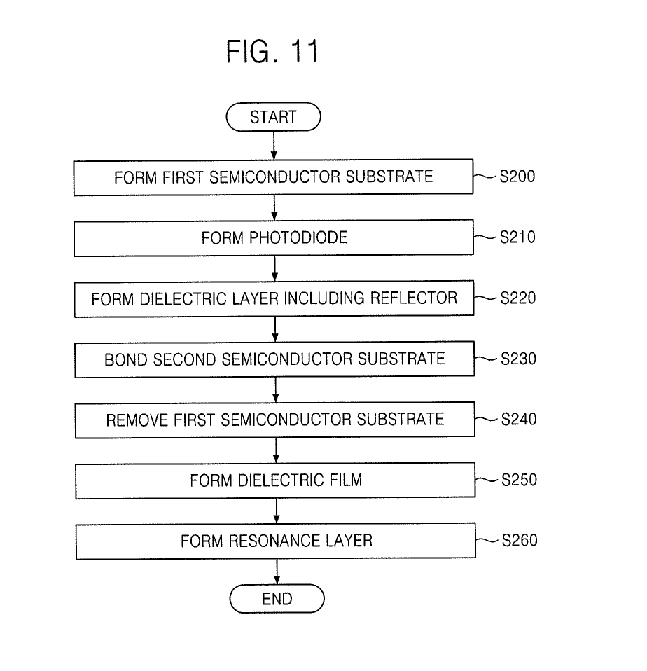

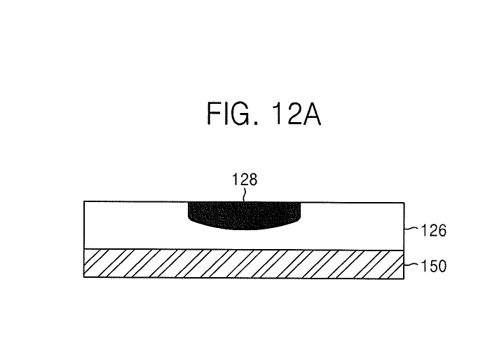

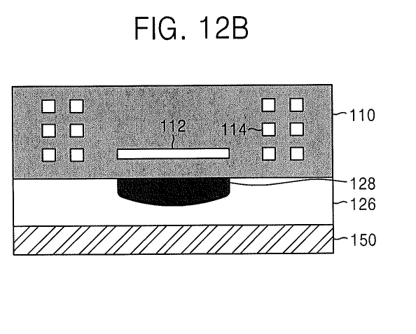

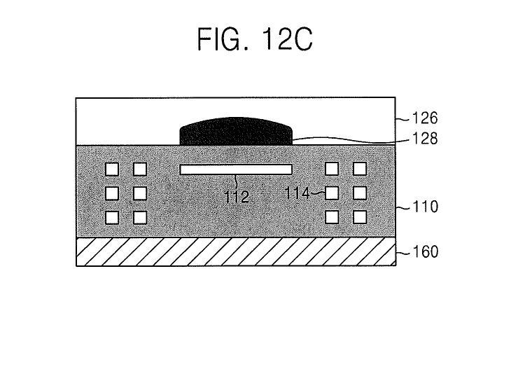

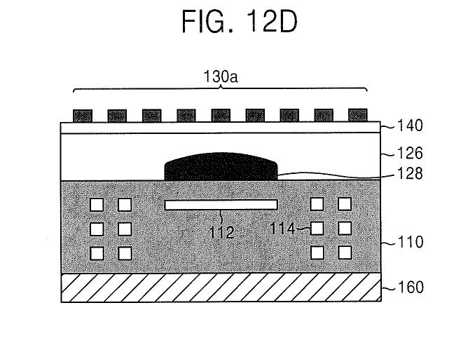

FIG. 11 illustrates a flowchart of a method of fabricating an image sensor according to other embodiments of the inventive concept. FIGS. 12A through 12D are sectional views of stages in the method illustrated in FIG. 11.

Referring to FIGS. 4 through 6, FIG. 11, and FIGS. 12A through 12D, the first semiconductor substrate 150 is formed in operation S200. The photo-electric conversion region 120b, e.g., a photodiode, is formed on the first semiconductor substrate 150 in operation S210. In detail, as shown in FIG. 12A, the first region 126 is formed on the first semiconductor substrate 150. The second region 128 is formed on a part of the first region 126 by, for example, doping the part of the first region 126 with impurities having a type opposite the type of the first region 126. In other words, impurities may be doped into the second region 128 to form the first region 126 within a portion of the second region 128, e.g., first surfaces of the first and second region 126 and 128 may face away from the first semiconductor substrate 150 and may be substantially coplanar.

As shown in FIG. 12B, the dielectric layer 110 including the reflector 112 is formed on a first surface of the photo-electric conversion region 120b, e.g., a side opposite the first semiconductor substrate 150, in operation S220. At this time, the reflector 112 may be formed after a part of the dielectric layer 110 is formed. Thereafter, the rest of the dielectric layer 110 may be formed. After the dielectric layer 110 is formed, as shown in FIG. 12C, the second semiconductor substrate 160 is bonded to the dielectric layer 110 in operation S230. The first semiconductor substrate 150 is removed in operation S140.

After the first semiconductor substrate 150 is removed, as shown in FIG. 12D, the resonance layer 130 is formed on a second surface of the photo-electric conversion region 120b from which the first semiconductor substrate 150 is removed, e.g., a side opposite the first surface. The dielectric film 140 may be formed on the light-absorbing layer 122 in operation S250, and the resonance layer 130a may be formed on the dielectric film 140 in operation S260.

For convenience of description, only a backside illumination (BSI) image sensor has been explained. However, the inventive concept is not restricted to the BSI image sensor and may also include a front side illumination (FSI) image sensor.

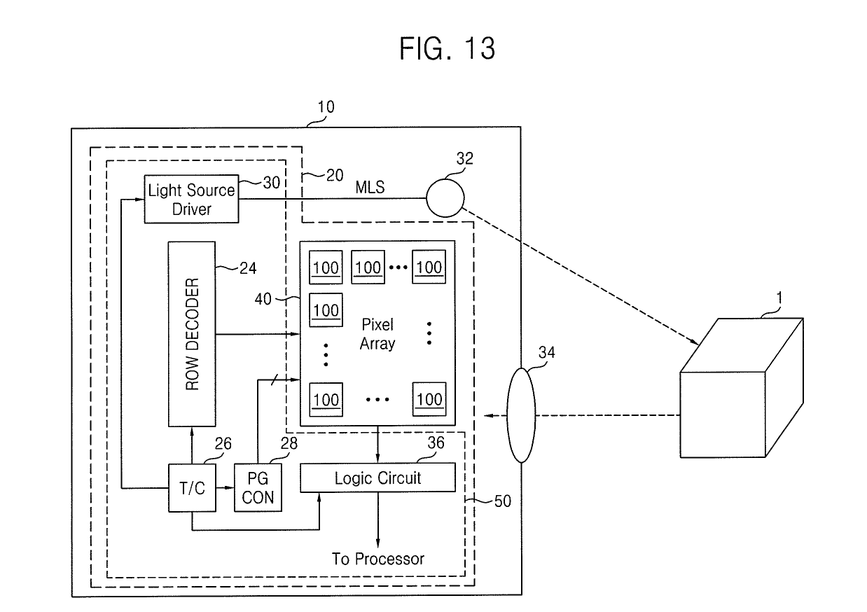

FIG. 13 illustrates a schematic block diagram of an image sensor 10 including pixels 100. Referring to FIG. 13, the image sensor 10 may measure a distance using a time-of-flight (TOF) principle. The image sensor 10 includes a semiconductor integrated circuit 20, a light source 32, and a lens module 34.

The semiconductor integrated circuit 20 includes a pixel array 40 including a plurality of the pixels 100, and an access control circuit 50. The access control circuit 50 includes a row decoder 24, a light source driver 30, a timing controller 26, a photogate controller 28, and a logic circuit 36.

Each of the pixels 100 included in the pixel array 40 may be one of the pixels 100-1 through 100-6 respectively illustrated in FIGS. 1 through 6.

The row decoder 24 selects one row from among a plurality of rows in response to a row address output from the timing controller 26. Here, a row is a set of depth pixels arranged in an X-direction in the pixel array 40. The photogate controller 28 may generate a plurality of photogate control signals and provide them to the pixel array 40 under the control of the timing controller 26.

For convenience of description, the photogate controller 28 will be described, but the inventive concept is not restricted thereto. For instance, the access control circuit 50 may include a photodiode controller that generates a plurality of photodiode control signals under the control of the timing controller 26 and provides them to the pixel array 40.

The light source driver 30 may generate a clock signal MLS for driving the light source 32 under the control of the timing controller 26. The light source 32 emits light to a target object 1 in response to the clock signal MLS. A light emitting diode (LED), an organic light emitting diode (OLED), or a laser diode may be used as the light source 32. The light source driver 30 provides the clock signal MLS or information about the clock signal MLS to the photogate controller 28.

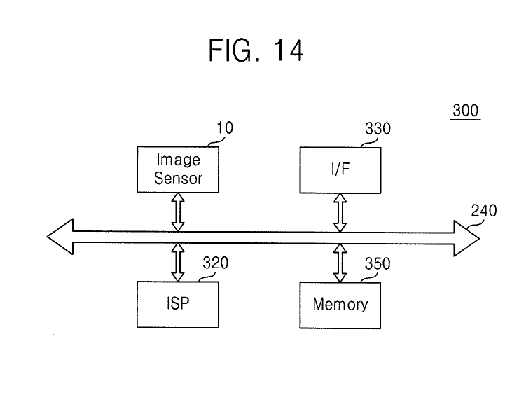

The logic circuit 36 may process signals sensed by the pixels 100 included in the pixel array 40 and output processed signals to a processor 320 in FIG. 14 under the control of the timing controller 26. The processor 320 may calculate a distance based on the processed signals. When the three-dimensional (3D) image sensor 10 includes the processor 320, the 3D image sensor 10 may be a distance measuring device.

The 3D image sensor 10 and the processor 320 may be implemented in separate chips, respectively. The logic circuit 36 may include an analog-to-digital conversion block (not shown) which converts sensed signals output from the pixel array 40 into digital signals. The logic circuit 36 may also include a correlated doubling sampling (CDS) block (not shown) which performs CDS on the digital signals output from the analog-to-digital conversion block.

Alternatively, the logic circuit 36 may include the CDS block that performs CDS on the sensed signals output from the pixel array 40 and an analog-to-digital conversion block that converts CDS signals output from the CDS block into digital signals. The logic circuit 36 may further include a column decoder which transmits an output signal of the analog-to-digital conversion block or an output signal of the CDS block to the processor 320 under the control of the timing controller 26.

Light reflected from the target object 1 is incident on the pixel array 40 through the lens module 34. The 3D image sensor 10 may include a plurality of light sources arranged in circle around the lens module 34, but only one light source 32 is illustrated in FIG. 13 for convenience of description. The light incident on the pixel array 40 through the lens module 34 may be sensed by the pixels 100. In other words, the light incident on the pixel array 40 through the lens module 34 may form an image.

FIG. 14 illustrates a schematic block diagram of an image processing device 300 including the image sensor 10 illustrated in FIG. 13. The image processing device 300 illustrated in FIG. 14 may be, e.g., a digital camera, a mobile phone equipped with a digital camera, or any type of electronic device including a digital camera. The image processing device 300 may process two-dimensional (2D) image information or 3D image information. The image processing device 300 includes the image sensor 10 illustrated in FIG. 13.

The image processing device 300 may also include the processor 320 controlling the operations of the image sensor 10.

The image processing device 300 may also include an interface 330. The interface 330 may be an image display device or an input/output device. Accordingly, the image processing device 300 may also include a memory device 350 that stores a still image or a moving image captured by the image sensor 10 under the control of the processor 320. The memory device 350 may be implemented by a non-volatile memory device. The non-volatile memory device may include a plurality of non-volatile memory cells.

The non-volatile memory device may be implemented by electrically erasable programmable read-only memory (EEPROM), flash memory, magnetic random access memory (MRAM), spin-transfer torque MRAM, conductive bridging RAM (CBRAM), ferroelectric RAM (FeRAM), phase-change RAM (PRAM) called ovonic unified memory, resistive RAM (RRAM or ReRAM), nanotube RRAM, polymer RAM (PoRAM), nano floating gate memory (NFGM), holographic memory, molecular electronic memory device, or insulator resistance change memory.

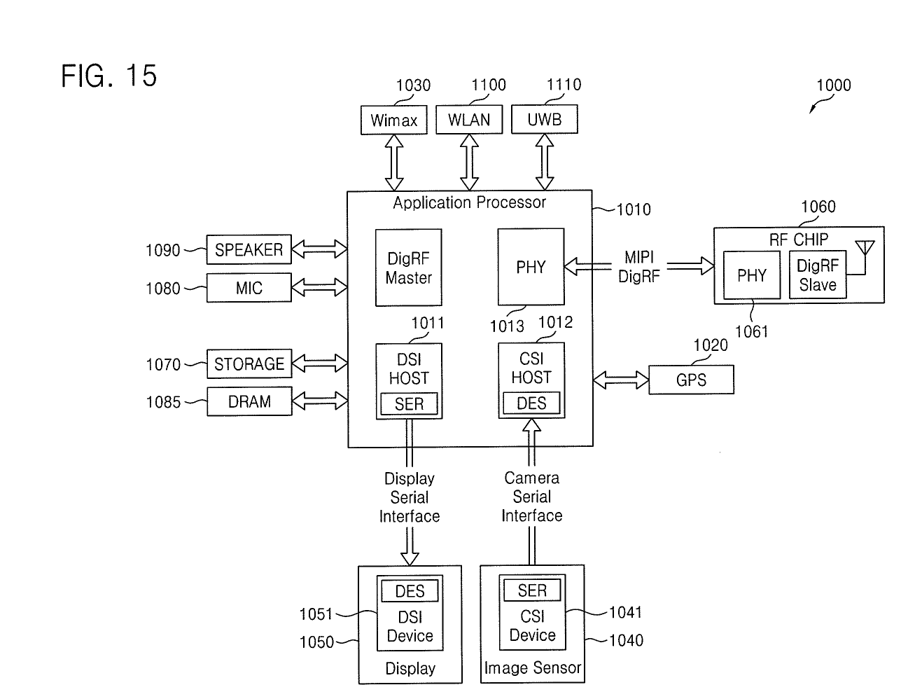

FIG. 15 illustrates a schematic block diagram of interface and an electronic system 1000 including an image sensor 1040 including the pixel illustrated in any one of FIGS. 1 through 6. Referring to FIG. 15, the electronic system 1000 may be implemented as a data processing device, e.g., a mobile phone, a personal digital assistant (PDA), a portable media player (PMP), Internet protocol television (IPTV), or a smart phone, which can use or support mobile industry processor interface (MIPI).

The electronic system 1000 includes an application processor 1010, the image sensor 1040 including any one of the pixels 100-1 through 100-6, and a display 1050.

A camera serial interface (CSI) host 1012 implemented in the application processor 1010 may perform serial communication with a CSI device 1041 included in the image sensor 1040 through CSI. At this time, an optical deserializer and an optical serializer may be implemented in the CSI host 1012 and the CSI device 1041, respectively.

A display serial interface (DSI) host 1011 implemented in the application processor 1010 may perform serial communication with a DSI device 1051 included in the display 1050 through DSI. At this time, an optical serializer and an optical deserializer may be implemented in the DSI host 1011 and the DSI device 1051, respectively.

The electronic system 1000 may also include a radio frequency (RF) chip 1060 communicating with the application processor 1010. A physical layer (PHY) 1013 of the application processor 1010 and a PHY 1061 of the RF chip 1060 may communicate data with each other according to MIPI DigRF. The electronic system 1000 may further include a global positioning system (GPS) 1020, a storage 1070, a microphone (MIC) 1080, a dynamic random access memory (DRAM) 1085, and a speaker 1090. The electronic system 1000 may communicate using a worldwide interoperability for microwave access (Wimax) 1030, a wireless local area network (WLAN) 1100, and an ultra-wideband (UWB) 1110.

As described above, according to some embodiments of the inventive concept, an image sensor increases the light absorption factor of a pixel by using a surface plasmon resonance, photonic crystal grating scattering, or total reflection caused by the reflector 122 and the ribbed materials 130a or 130b arranged on the photo-electric conversion regions 120a or 120b, thereby improving sensitivity. In addition, the image sensor collects light even when incident light is oblique light, thereby further improving sensitivity.

In contrast, a conventional image sensor includes a microlens or a thick light-absorbing layer in order to increase the light absorption factor of the pixel. However, when the microlens is used in the conventional image sensor, the sensitivity of the image sensor may be decreased when light to be sensed is oblique light, crosstalk may occur between the pixels, and the size of the image sensor may be increased. When the thick light-absorbing layer is used in the conventional image sensor, the image sensor may consume a lot of power, may require high manufacturing costs, may have crosstalk between the pixels, and may have a large size.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An image sensor, comprising:
a dielectric layer including a reflector;
a photo-electric conversion region on the dielectric layer; and
a resonance layer on the photo-electric conversion region, the resonance layer including ribbed materials arranged in a concentric pattern.

2. The image sensor of claim 1, wherein the photo-electric conversion region includes:
a light-absorbing layer below the resonance layer; and
a photogate between the light-absorbing layer and the dielectric layer.

3. The image sensor of claim 2, further comprising a dielectric film between the light-absorbing layer and the resonance layer.

4. The image sensor of claim 2, wherein the light-absorbing layer has a thickness of about 0.01 μm to about 20 μm.

5. The image sensor of claim 1, wherein the photo-electric conversion region includes an electron donating material and an electron accepting material.

6. The image sensor of claim 1, wherein the resonance layer is configured to support surface plasmon resonance at a wavelength of light to be sensed.

7. The image sensor of claim 1, wherein the ribbed materials have a negative real value of permittivity at a wavelength of light to be sensed.

8. The image sensor of claim 1, wherein the ribbed materials are patterns spaced apart from each other, the patterns having a permittivity relatively greater than a permittivity of a material in a space between adjacent patterns.

9. The image sensor of claim 1, wherein a distance between the photo-electric conversion region and the reflector is 700 nm or less.

10. The image sensor of claim 1, wherein the dielectric layer includes at least one of SiO₂, SiON, HfO₂, and Si₃N₄.

11. An image processing device, comprising:
the image sensor of claim 1; and
a processor configured to control an operation of the image sensor.

12. A method of fabricating an image sensor, the method comprising:
forming a first semiconductor substrate;
forming a photo-electric conversion region on the first semiconductor substrate;
forming a dielectric layer on a first surface of the photo-electric conversion region, the dielectric layer including a reflector;
bonding a second semiconductor substrate to the dielectric layer and removing the first semiconductor substrate; and
forming a resonance layer on a second surface of the photo-electric conversion region, the resonance layer including ribbed materials arranged in a concentric pattern.

13. The method of claim 12, wherein forming the photo-electric conversion region includes:
forming a light-absorbing layer on the first semiconductor substrate; and
forming a photogate on a part of the first surface.

14. The method of claim 12, wherein forming the photo-electric conversion region includes forming a first region of an electron donating material and a second region of an electron accepting material on the first semiconductor substrate.

15. The method of claim 12, wherein forming the resonance layer includes:
forming a dielectric film on the second surface; and
forming the resonance layer on the dielectric film.

16. An image sensor, comprising:
a dielectric layer including a reflector;
a photo-electric conversion region on the dielectric layer; and
a resonance layer on the photo-electric conversion region, the resonance layer including ribbed materials arranged in a concentric pattern on the photo-electric conversion region, and the photo-electric conversion region being between the resonance layer and the dielectric layer.

17. The image sensor of claim 16, wherein the ribbed material of the resonance layer includes a plurality of closed-shaped patterns spaced apart from each other.

18. The image sensor of claim 17, wherein a distance between adjacent patterns in the resonance layer is based on a wavelength of light to be sensed and on a distance between a bottom of the resonance layer and a bottom of the photo-electric conversion region.

19. The image sensor of claim 16, wherein the photo-electric conversion region is between the resonance layer and the reflector of the dielectric layer.

20. The image sensor of claim 16, further comprising a microlens on the photo-electric conversion region, the resonance layer being between the microlens and the photo-electric conversion region.
